(19) United States
(12) Patent Application Publication
(10) Pub. No.: US 2005/0055618 A1
(43) Pub. Date: Mar. 10, 2005

(54) Test arrangement and method for selecting a test mode output channel

(76) Inventors: Thomas Finteis, Munchen (DE); Bjorn Flach, Vila do Conde (PT); Klaus Hoffman, Munchen (DE); Andreas Logisch, Munchen (DE); Wolfgang Ruf, Friedberg (DE); Martin Schnell, Munchen (DE)

Correspondence Address: JENKINS & WILSON, PA, 3100 TOWER BLVD, SUITE 1400, DURHAM, NC, 27707, US

(21) Appl. No.: 10/926,371

(22) Filed: Aug. 25, 2004

(30) Foreign Application Priority Data
Sep. 4, 2003 (DE) 10340828.2

(51) Int. Cl. G06F 11/00; G01R 31/28

(52) U.S. Cl. 714/742

(57) ABSTRACT

The invention provides a test arrangement for testing circuit units under test (101, 101a-101n) having a test apparatus for holding the circuit units under test (101, 101a-101n), input/output channels (DQ0-DQn) for connecting the circuit units under test (101, 101a-101n) to the test apparatus and for data interchange, and test mode output channels (103, 103a-103n) for outputting a test result signal (104, 104a-104n), where at least one diversion unit (102, 102a-102n) for connecting one of the test mode output channels (103, 103a-103n) to one of the input/output channels (DQ0-DQn) is provided in the circuit units under test (101, 101a-101n) so that the test result signal (104, 104a-104n) which is output from the circuit unit under test (101, 101a-101n) can be diverted from the circuit unit under test (101, 101a-101n) to a prescribable one of the input/output channels (DQ0-DQn).

The present invention relates generally to a test arrangement for testing circuit units under test, and relates particularly to a test arrangement in which a test mode output channel in the circuit units under test can be selected. The invention also relates to a corresponding test method.

The invention relates specifically to a test arrangement for testing circuit units under test which has a test apparatus for holding the circuit units under test, input/output channels for connecting the circuit units under test to the test apparatus and for interchanging test data with the circuit units under test, and test mode output channels for outputting a test result signal from the circuit units under test.

The invention also relates especially to a test method for testing circuit units under test in which the steps of inserting the circuit units under test into a test apparatus, connecting the circuit units under test to the test apparatus by means of input/output channels, interchanging test data with the circuit units under test via the input/output channels and outputting a test result signal from the circuit units under test using test mode output channels are executed.

To increase a level of parallelism for testing circuit units under test in a test apparatus, advanced compression test modes (ACTMs) are currently introduced into the manufacture of circuit units. In this context, the circuit units under test are connected in parallel by means of their input/output channels and are actuated in parallel in order to ensure an optimum level of parallelism during testing.

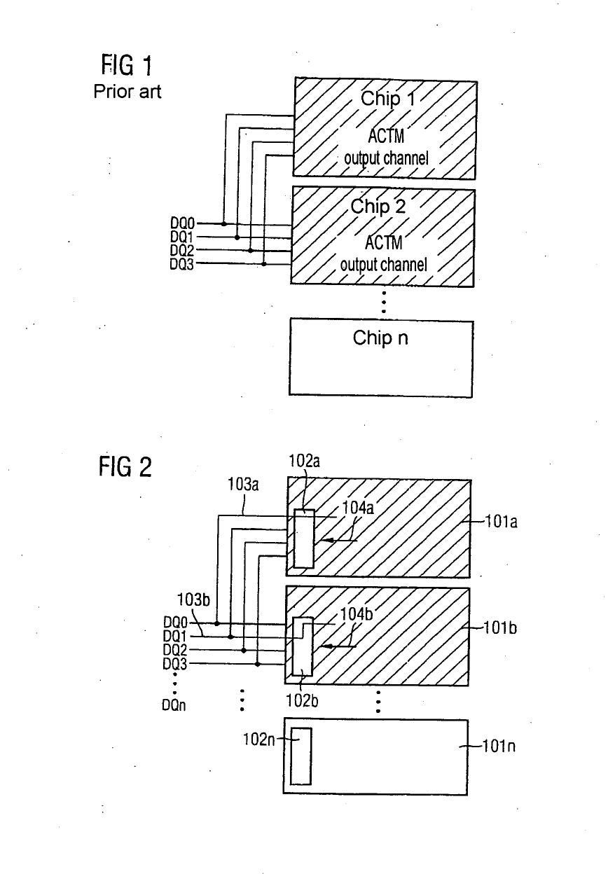

FIG. 1 shows a conventional test arrangement for testing chips under test 1, 2, . . . , n. By way of example, FIG. 1 shows how two circuit units under test, i.e. a chip 1 and a chip 2, are connected to input/output channels DQ0, DQ1, DQ2 and DQ3.

It may be seen from FIG. 1 that all input/output channels are shared by chips under test 1, . . . n. When using the aforementioned advanced compression test mode (ACTM), the problem arises that the respective ACTM output signal from a chip needs to be output via the input/output channels DQ0-DQ3. Since two or more chips share the input/output channels, as already mentioned, the conventional test arrangement encounters the drawback that the chips under test which use the same respective connection pin for outputting the ACTM output signal overlay the output signals on one of the input/output channels DQ0-DQ3.

By way of example, FIG. 1 shows that the chips under test have the ACTM output channel connected to the first input/output channel DQ0 of the chip under test. There is thus the significant drawback that it is not possible to provide a level of parallelism for testing the chips under test, since the ACTM output signals must not be overlaid on an input/output channel.

Particularly in the case of stacked chips which form a full chip, the conventional test arrangement has considerable drawbacks. To solve the problem, it has been proposed that appropriate wiring be provided within a stacked full chip or a magazine such that ACTM output signals are prevented from being overlaid. In this context, the output signals from a plurality of chips have been diverted to different test channels. However, this conventional procedure has the significant drawback that package-internal wiring cannot be changed in every case in stacked chips (“stacked components”), for example.

It is thus a drawback of conventional test arrangements and corresponding test methods that outputting ACTM output signals onto input/output channels which are used by a plurality of chips lowers a level of parallelism for testing chips under test.

It is therefore an object of the present invention to provide a test arrangement which increases a level of parallelism for testing circuit units under test and reduces test times.

The invention achieves this object by means of a test arrangement having the features of patent claim 1.

In addition, the object is achieved by a method for testing circuit units under test which is specified in patent claim 8.

Further refinements of the invention can be found in the subclaims.

A fundamental concept of the invention is for the circuit units under test which are inserted into a test apparatus in the test arrangement to contain an additional logic circuit unit which diverts an ACTM output signal from a circuit unit under test to a prescribable one of the input/output channels in the circuit unit under test.

For this purpose, the inventive test arrangement provides at least one diversion unit for connecting one of the test mode output channels to one of the input/output channels such that the test result signal which is output from the circuit unit under test can be diverted from the circuit unit under test to a prescribable one of the input/output channels. In this context, one of the test mode output channels is connected to one of the input/output channels in the circuit unit under test.

The additional logic circuit unit inserted into the circuit unit under test thus permits an ACTM output signal being output to be diverted to a prescribable input/output connection pin (I/O pin).

One advantage of the present invention is thus that it is possible to reduce a test time which is required for testing circuit units under test, since a level of parallelism for testing the circuit units under test is increased. The increase in the level of parallelism for testing circuit units under test comes from the fact that the ACTM output signals are not overlaid on one specific input/output channel but rather can be diverted in prescribable fashion to different input/output channels or can be provided thereon.

The inventive test arrangement is thus expediently designed such that even stacked full chips, which comprise different circuit units and are accommodated in a single package, can be tested efficiently and with a high level of parallelism.

The inventive test arrangement for testing circuit units under test essentially has:
a) a test apparatus for holding the circuit units under test, the circuit units under test being electrically connected to the test apparatus using their appropriate input/output connection pins;
b) input/output channels for connecting the circuit units under test to the test apparatus and for interchanging test data with the circuit units under test; and
c) test mode output channels for outputting a test result signal from the circuit units under test, the circuit units under test each having at least one diversion unit for connecting one of the test mode output channels to one of the input/output channels such that the test result signal which is output from the circuit unit under test can be diverted from the circuit unit under test to a prescribable one of the input/output channels.

In addition, the inventive method for testing circuit units under test essentially has the following steps:
a) the circuit units under test are inserted into a test apparatus, and they are electrically connected to the test apparatus;
b) the circuit units under test are connected to the test apparatus by means of input/output channels;
c) test data are interchanged with the circuit units under test via the input/output channels; and
d) a test result signal is output from the circuit units under test using test mode output channels, with, additionally, at least one diversion unit being used to divert the test result signal which is output from the circuit unit under test to a prescribable one of the input/output channels by connecting one of the test mode output channels to one of the input/output channels in the circuit unit under test.

The subclaims contain advantageous developments and improvements of the respective subject matter of the invention.

In line with one preferred development of the present invention, the input/output channels for connecting the test apparatus to the circuit units under test and for data interchange with the circuit units under test are provided in parallel for all circuit units under test.

In line with a further preferred development of the present invention, the diversion units in the circuit units under test also each have at least one selection unit for outputting a selection signal which specifies that of the input/output channels which is to be connected to the test mode output channel in the circuit unit under test in order to divert the test result signal from the circuit unit under test to the specified input/output channel.

In line with yet another preferred development of the present invention, the diversion units in the circuit units under test also each have at least one connecting unit which can be used to connect the test mode output channel in the circuit unit under test to the input/output channel specified on the basis of the selection signal which is output by the selection unit.

Preferably, the connecting unit is in the form of a demultiplexing unit which demultiplexes the test result signal on the test mode output channel for the input/output channels.

In line with yet another preferred development of the present invention, the at least one selection unit in the circuit unit under test is provided as a 4-bit register in order to output the selection signal.

Preferably, an ACTM output signal, i.e. a test result signal, can then be diverted in specifiable fashion to one of 16 input/output channels.

In line with yet another preferred development of the present invention, the circuit units under test are stacked in an electronic chip, i.e. a full chip.

In line with yet another preferred development of the present invention, the circuit units under test are tested using an ACTM (Advanced Compression Test Mode).

The logic circuit units inserted into the circuit units under test are used, in addition to the ACTM test mode, for advantageously permitting diversion of the corresponding test result signals.

In line with yet another preferred development of the present invention, that of the input/output channels which is to be connected to the test mode output channel in the circuit unit under test is specified by means of selective addressing using an identification element for the circuit unit under test in order to divert the test result signal from the circuit unit under test to the specified input/output channel.

In line with yet another preferred development of the present invention, that of the input/output channels which is to be connected to the test mode output channel in the circuit unit under test is specified using a circuit unit selection signal provided via a selection channel in order to divert the test result signal from the circuit unit under test to the specified input/output channel.

In line with yet another preferred development of the present invention, that of the input/output channels which is to be connected to the test mode output channel in the circuit unit under test is stipulated using a bond and/or using laser fusing in order to divert the test result signal from the circuit unit under test to the specified input/output channel.

Exemplary embodiments of the invention are shown in the drawings and are explained in more detail in the description below.

In the drawings:

FIG. 1 shows a conventional test arrangement for testing chips under test;

FIG. 2 shows a test arrangement based on a preferred exemplary embodiment of the present invention;

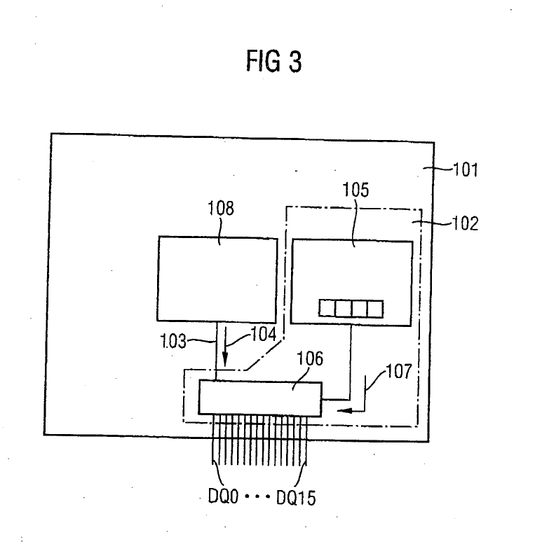

FIG. 3 shows the design of a circuit unit under test with logic circuit units additionally inserted into the circuit unit under test in line with a preferred exemplary embodiment of the present invention; and

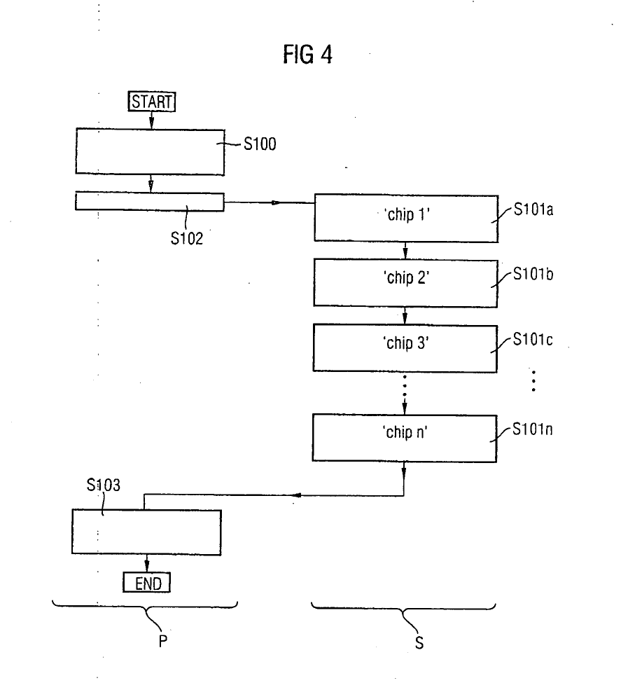

FIG. 4 shows a flowchart of the inventive test method.

FIG. 2 shows a block diagram of a test arrangement for testing circuit units under test 101a, 101b, . . . 101n in line with a preferred exemplary embodiment of the present invention. The block diagram shown in FIG. 2 shows two circuit units under test 101a, 101b.

It should be pointed out that the inventive test method for testing circuit units under test allows virtually any number of circuit units under test 101a-101n to be connected in parallel.

The circuit units under test are connected in parallel to input/output channels DQ0-DQn. In the exemplary embodiment shown in FIG. 2, four input/output channels DQ0, DQ1, DQ2 and DQ3 are provided. The circuit units under test 101a-101n are tested using an advanced compression test mode, i.e. an ACTM, which is in a form such that a logic 1 is output on one of the input/output channels DQ0-DQn as a test result signal 104a-104n if the circuit unit under test 101a-101n is faultless, i.e. “pass” is indicated.

On the other hand, the circuit unit under test 101a-10n has a fault if the test result signal 104a-104n which is output on one of the input/output channels DQ0-DQn has a logic “0”, i.e. if a “fail” is indicated. To obtain a test result signal 104a-104n which corresponds to a respective circuit unit under test 101a-101n, different processing procedures are performed with the appropriate circuit unit under test 101a-101n in line with the ACTM method.

By way of example, the test mode sets specific registers, writes to the register by specifying a specific address and reads the register again on the basis of X and Y coordinates. A comparison between an actual data signal and a nominal data signal is likewise provided on the circuit unit under test 101a-101n by the ACTM method.

To carry out the ACTM method, the circuit units under test 101a-101n, which may also be provided as stacked circuit units (stacked chips), are mounted onto a hifix adapter in a test arrangement (not shown) which electrically connects them to the test apparatus. The inventive test arrangement is particularly advantageous for stacked chips, i.e. for components which are arranged inside a package and whose wiring inside the package can no longer be changed. In line with the invention, each circuit unit under test 101a-101n has a diversion unit 102a-102n. This diversion unit 102a-102n will be described in detail below with reference to FIG. 3.

The block diagram in FIG. 2 illustrates that the test result signals 104a-104n which are output by the circuit units under test 101a-10n are output on different test mode output channels 103a-103n which are respectively associated with the test result signals 104a-104n. This is possible because the diversion unit 102a-102n in a specific circuit unit under test 101a-10n is capable of diverting the corresponding test result signal 104a-104n to a respective different one of the input/output channels DQ0-DQ3.

Although FIG. 2 shows four different input/output channels DQ0, DQ1, DQ2 and DQ3, it should be understood that the invention is not limited to four input/output channels DQ0-DQ3 but rather that any number of input/output channels may be addressed using the corresponding diversion units 102a-102n. Preferably, 16 input/output channels DQ0-DQ15 are currently provided in circuit units under test, particularly in circuit units under test which are provided as stacked components, as illustrated below with reference to FIG. 3.

The diversion units 102a-102n illustrated in the circuit units under test 101a-10n thus ensure, on the basis of a selection signal (described below), that the corresponding test result signals 104a-104n are not overlaid on a single input/output channel DQ0-SQ3 simultaneously, as is the case in test arrangements based on the prior art. Rather, the inventive test arrangement can be used to output each test result signal 104a-104n on a dedicated input/output channel DQ0-DQn in the circuit units under test 101a-101n, provided that an adequate number of input/output channels DQ0-DQn exists.

FIG. 3 shows the logic circuit unit arranged in a circuit unit under test 101 in more detail, said logic circuit unit being in the form of a diversion unit 102. The circuit unit under test 101 which is shown in FIG. 3 contains, besides the diversion unit 102, a test mode unit 108 which provides for a test sequence, for example in line with the ACTM (Advanced Compression Test Mode) method. The test mode unit 108 outputs a test result signal 104 on a test mode output channel 103.

It should be pointed out that all of the circuit units 101a-101n which are to be tested in a test in a test arrangement are in the form of the circuit unit under test 101 which is shown in FIG. 3, in order to provide an optimal increase in a level of parallelism for testing.

In line with the invention, the test mode output channel 103 is diverted to a prescribable one of the input/output channels DQ0-DQ15 (the exemplary embodiment of the present invention which is shown in FIG. 3 has 16 input/output channels DQ0-DQ15). The diversion is effected using a connecting unit 106 which is arranged in the diversion unit 102 in the circuit unit under test 101 and takes a prescribed selection signal 107 as a basis for providing a diversion for the test result signal 104 to a prescribable one of the input/output channels DQ0-DQ15.

The diversion provided in the connecting unit 106 may be achieved in different ways. By way of example, the connecting unit 106 may be in the form of a demultiplexing unit which demultiplexes the test result signal 104 on the test mode output channel 103 for the corresponding input/output channels DQ0-DQ15. For this purpose, the diversion unit 102 in the circuit unit under test 101 contains a selection unit 105 (it should be pointed out that such a selection unit 105a-105n may be provided in each of the circuit units under test 101a-10n) which outputs a selection signal 107. In line with one preferred development of the present invention, the selection unit 105 is provided as a 4-bit register in order to be able to address or select the 16 input/output channels DQ0-DQ15 selectively.

In this context, the 4-bit register may be set to a particular value before the circuit units under test are tested, this value then determining the desired output connection pin for outputting the ACTM output signal. The remaining output channels are in a high impedance state in order to avoid disturbing the one driving channel.

It should be pointed out that the input/output channels DQ0-DQ15 may be provided as I/O channels. The inventive test arrangement means that it is now possible for the test mode output channels 103a-103n to be diverted to different input/output channels DQ0-DQn. In a full system, a test result signal 104a from a circuit unit under test 101a can thus be read out on an input/output channel DQ0, the test result signal 104b from the circuit unit under test 101b can be read out on an input/output channel DQ1 etc., see also FIG. 2.

In addition, it is possible for that of the input/output channels DQ0-DQ15 which is to be connected to the test mode output channel 103 in the circuit unit under test 101 to be specified by means of selective addressing using an identification element for the circuit unit under test 101, in order to divert the test result signal 104 from the circuit unit under test to the specified input/output channel. In addition, it is advantageous if that of the input/output channels DQ0-DQ15 which is to be connected to the test mode output channel 103 in the circuit unit under test 101 is specified using a circuit unit selection signal provided via a selection channel, in order to divert the test result signal 104 from the circuit unit under test 101 to the specified input/output channel.

The inventive method expediently permits that of the input/output channels DQ0-DQ15 which is to be connected to the test mode output channel 103 in the circuit unit under test 101 to be stipulated using a bond and/or using laser fusing, in order to divert the test result signal 104 from the circuit unit under test to the specified input/output channel DQ0-DQ15.

To test a 512M D14 DDR SDRAM chip, for example, the inventive test arrangement is advantageously used. Such a chip is produced in a stacked version. This stacked chip contains two 512M D14 chips and thus has a storage capacity of 1024 Mbits or 1 Gbit.

In the case of this chip (circuit unit under test), all connection pins are wired up in parallel inside, with the exception of a connection pin for the CS (Chip Select) signal and the CKE (Clock Enable) signal. When testing such a stacked chip, it is not possible to operate the two aforementioned individual chips in the package simultaneously, since in this case, as already mentioned above with reference to FIG. 1 in the explanation of the conventional test method, the ACTM output signal would be overlaid on one respective input/output channel. When using the conventional method, the first chip would first of all be activated and tested with a signal CS1. Next, the conventional method would require that the second chip in the chip package be activated and tested with a signal CS2. This increases the test time by a factor of 2 as compared with a 521M D14 (which is not stacked).

It is advantageously possible to use the inventive test arrangement to test both individual chips (the first chip and the second chip) in the chip package in parallel. A total test time for the stacked chip corresponds to the test time for a single one of the two chips. Hence, test time is saved and the test costs are reduced.

FIG. 4 shows a flow chart of the inventive test method. When the inventive test method for testing circuit units under test has started, all circuit units under test are initialized in an initialization step S100. This initialization step is provided when the power is started up or when the circuit units under test are connected to a power supply. The processing then advances to a test mode step S102.

In the test mode step S102, the processing enters an advanced compression test mode (ACTM). In line with the invention, each individual circuit unit under test 101a-101n is then selected in a corresponding selection step S101a-S101n, i.e. “chip1”, “chip2”, “chip3”, . . . “chipn” are selectively addressed. In the selection steps S101a-S101n, a unique connection pin is set as a test mode output channel 103a-103n. When the ACTM output connection pin has been chosen for each of the circuit units under test 101a-101n, it is possible to execute a test sequence for all parallel-connected circuit units under test 101a-101n in a parallel test step S103. The output of the ACTM logic can be evaluated by the test apparatus, because each circuit unit under test 101a-101n outputs the ACTM output signal on a different input/output channel.

In the part denoted by S in FIG. 4, each circuit unit under test 101a-101n is selected selectively, while the circuit units under test 101a-101n are tested in parallel in the part denoted by P in FIG. 4.

With regard to the conventional test arrangement shown in FIG. 1, reference is made to the introduction to the description.

Although the present invention has been described above using preferred exemplary embodiments, it is not limited thereto but rather can be modified in a wide variety of ways.

The invention is also not limited to the application options mentioned.

List of Reference Symbols

In the figures, identical reference symbols denote components or steps which are the same or have the same function.
101, 101a-101n Circuit unit under test
102, 102a-102n Diversion unit
103, 103a-103n Test mode output channel
104, 104a-104n Test result signal
105, 105a-105n Selection unit
106 Connecting unit
107 Selection signal
108 Test mode unit
DQ0-DQn Input/output channels
S100 Initialization step
S101a-S101n Selection step
102 Test mode step
S103 Parallel test step

1. A test arrangement for testing circuit units under test having:
a) a test apparatus for holding the circuit units under test;
b) input/output channels for connecting the circuit units under test to the test apparatus and for interchanging test data with the circuit units under test; and
c) test mode output channels for outputting a test result signal from the circuit units under test,
wherein the circuit units under test each have:
d) at least one diversion unit for connecting one of the test mode output channels to one of the input/output channels such that the test result signal which is output from the circuit unit under test can be diverted from the circuit unit under test to a prescribable one of the input/output channels.

2. The test arrangement as claimed in claim 1, wherein the input/output channels for connecting the test apparatus to the circuit units under test and for data interchange with the circuit units under test are provided in parallel for all circuit units under test.

3. The test arrangement as claimed in claim 1, wherein the diversion units in the circuit units under test also each have at least one selection unit for outputting a selection signal which specifies that of the input/output channels which is to be connected to the test mode output channel in the circuit unit under test in order to divert the test result signal from the circuit unit under test to the specified input/output channel.

4. The test arrangement as claimed in claim 1 or 3, wherein the diversion units in the circuit units under test also each have at least one connecting unit which can be used to connect the test mode output channel in the circuit unit under test to the input/output channel specified on the basis of the selection signal which is output by the selection unit.

5. The test arrangement as claimed in claim 4, wherein the connecting unit is in the form of a demultiplexing unit which demultiplexes the test result signal on the test mode output channel for the input/output channels.

6. The test arrangement as claimed in claim 3, wherein the at least one selection unit in the circuit unit under test is provided as a 4-bit register in order to output the selection signal.

7. The test arrangement as claimed in claim 1, wherein the circuit units under test are stacked in an electronic chip.

8. A method for testing circuit units under test, having the following steps:
a) inserting the circuit units under test into a test apparatus;
b) connecting the circuit units under test to the test apparatus by means of input/output channels;
c) interchanging test data with the circuit units under test via the input/output channels; and
d) outputting a test result signal from the circuit units under test using test mode output channels,
wherein the method also has the following steps:
e) using at least one diversion unit divert the test result signal which is output from the circuit unit under test to a prescribable one of the input/output channels by connecting the test mode output channel in the circuit unit under test to a prescribed one of the input/output channels in the circuit unit under test.

9. The method as claimed in claim 8, wherein the input/output channels for connecting the test apparatus to the circuit units under test and for data interchange with the circuit units under test are provided in parallel for all circuit units under test.

10. The method as claimed in claim 8, wherein that of the input/output channels which is to be connected to the test mode output channel in the circuit unit under test is specified using a selection signal which is output from a selection unit provided in the diversion units in the circuit unit under test in order to divert the test result signal from the circuit unit under test to the specified input/output channel.

11. The method as claimed in claim 8, wherein the test mode output channel in the circuit unit under test is connected to the input/output channel specified on the basis of the selection signal which is output by the selection unit using a connecting unit which is provided in the diversion units in the circuit unit under test.

12. The method as claimed in claim 11, wherein the test result signal provided on the test mode output channel in the circuit unit under test is demultiplexed for the input/output channels in the circuit unit under test using a connecting unit in the form of a demultiplexing unit.

13. The method as claimed in claim 8, wherein the circuit units under test are tested using ACTM (Advanced Compression Test Mode).

14. The method as claimed in claim 8, wherein that of the input/output channels which is to be connected to the test mode output channel in the circuit unit under test is specified by means of selective addressing using an identification element for the circuit unit under test in order to divert the test result signal from the circuit unit under test to the specified input/output channel.

15. The method as claimed in claim 8, wherein that of the input/output channels which is to be connected to the test mode output channel in the circuit unit under test is specified using a circuit unit selection signal provided via a selection channel in order to divert the test result signal from the circuit unit under test to the specified input/output channel.

16. The method as claimed in claim 8, wherein that of the input/output channels which is to be connected to the test mode output channel in the circuit unit under test is stipulated using a bond and/or using laser fusing in order to divert the test result signal from the circuit unit under test to the specified input/output channel.
